(19) United States
(12) Patent Application Publication
(10) Pub. No.: US 2011/0177674 A1
(43) Pub. Date: Jul. 21, 2011

(54) PROCESSING OF MULTILAYER SEMICONDUCTOR WAFERS

(75) Inventors: Aleksej Rodin, Vilnius (LT); Adrian Boyle, Knavinstown (IE); Niall Brennan, Dublin (IE); Joseph Callaghan, Dublin (IE)

(73) Assignee: Electro Scientific Industries, Inc., Portland, OR (US)

(21) Appl. No.: 12/933,389

(22) PCT Filed: Mar. 16, 2009
(86) PCT No.: PCT/EP2009/053061

§ 371 Date: Mar. 11, 2011

(30) Foreign Application Priority Data
Mar. 18, 2008 (GB) 0805037.9

(51) Int. Cl. H01L 21/78; G21G 5/00; H01L 21/302

(52) U.S. Cl. 438/460; 250/492.2; 118/639; 156/345.11; 257/E21.599

(57) ABSTRACT

A method and apparatus for machining, or forming a feature in, a patterned silicon wafer includes removing portions of surface layers on the wafer using a first pulsed laser (4) beam with a pulse width between 1 ps and 1000 ps; and removing portions of bulk silicon (1) underlying the surface layers from the wafer using a second pulsed laser (5) beam with a wavelength between 200 nm and 1100 nm. Re-deposited silicon may be removed from the wafer by etching.

This invention relates to processing multilayer semiconductor wafers.

A semiconductor wafer typically includes a number of layers of metals and insulators on a surface which are used to define active circuitry of devices produced from the wafer. With developing wafer technology, these layers present problems in processes subsequent to their formation that are necessary to create the active devices from the wafer.

The problems are caused mainly by new materials used in the surface layers and a requirement for smaller feature sizes for lower costs, thinner wafers and smaller devices. Specific processes which are problematic are wafer dicing, which traditionally involves using an abrasive saw to cut the wafer into individual die, and an interconnect formation process which traditionally has used wired bonded from one region to a next to form a wire bond interconnect. A competing approach to the wire bond is to drill interconnecting vias between opposed faces of a wafer and to form interconnects on the underside of the resulting device or on to another device. This technology is termed “through via” technology. In a similar way, blind vias allow electrical contact with an internal layer of the wafer. These processes are used as part of what is known as “via last” processing, in which an interconnecting via is drilled on manufactured wafers.

While known etch techniques can provide a solution, at least in via drilling to these processing problems, the cost is generally high because of technical obstacles such as particularly low throughput, via geometry and material sensitivity. Briefly, the via taper angle typically required is not perfectly straight and this is difficult to achieve by etching but is possible with laser drilling. Also, where metals and insulators are stacked, different etch processes are often required for each and these processes are slow.

It is an object of the present invention at least to ameliorate the aforesaid deficiencies in the prior art.

According to a first aspect of the invention, there is provided a method of machining, or forming a feature in, a patterned silicon wafer comprising: removing portions of surface layers on the wafer using a first pulsed laser beam with a pulse width between 1 ps and 1000 ps; and removing portions of bulk silicon underlying the surface layers from the wafer using a second pulsed laser beam with a wavelength between 200 nm and 1100 nm.

Conveniently, the method further comprises removing re-deposited silicon from the wafer by etching.

Advantageously, the first pulsed laser beam has wavelength between 1000 nm and 1100 nm.

Advantageously, the second pulsed laser beam is produced by a Q-switched laser with a pulse width in the range 1 ns to 500 ns

Alternatively, the second pulsed laser beam has a pulse width between 1 ps and 1000 ps.

Conveniently, the method comprises etching with xenon difluoride.

Conveniently, the method comprises a wet chemical etch.

Alternatively, the method comprises a dry chemical etch.

Advantageously, the etch process is used to clear at least one of the surface of the wafer and the machined walls of the wafer of debris.

Advantageously the method comprises forming an interconnecting through via or blind via in the wafer.

Alternatively, the method comprises dicing or singulating a wafer.

According to a second aspect of the invention there is provided an apparatus arranged to machine, or form a feature in, a patterned silicon wafer comprising: a first laser arranged to provide a first pulsed laser beam with a pulse width between 1 ps and 1000 ps arranged to remove portions of surface layers on the wafer; a second laser arranged to provide a second pulsed laser beam with a wavelength between 200 nm and 1100 nm arranged to remove portions of bulk silicon underlying the surface layers from the wafer; and means for targeting the first and second laser beams at a same location on the wafer.

Advantageously, the apparatus further comprises etching means arranged to remove re-deposited silicon from the wafer by etching.

Advantageously the first pulsed laser beam has a wavelength between 1000 nm and 1100 nm.

Advantageously the second laser is a Q-switched laser with a pulse width in the range 1 ns to 500 ns.

Alternatively, the second pulsed laser beam has a pulse width between 1 ps and 1000 ps.

Advantageously, the apparatus comprises comprising aligning means for aligning paths of the first and second laser beams coaxially for targeting at a same location on the wafer.

Conveniently, the etching means is arranged to etch with xenon difluoride.

Conveniently, the etching means is arranged to provide a wet chemical etch.

Alternatively, the etching means is arranged to provide a dry chemical etch.

Advantageously, the etching means is arranged to provide a wet chemical etch to clear the surface of the wafer and machined walls of the wafer of debris.

Advantageously, the apparatus is arranged to form an interconnecting through via or blind via in the wafer.

Alternatively, the apparatus is arranged to dice or singulate a wafer.

Advantageously, the apparatus further comprises synchronising means arranged to sequence pulse emissions from the first and second lasers to deliver pulses from each laser in a predetermined sequence to the wafer.

Advantageously, the apparatus further comprises a machine vision system arranged to image through the laser beam path to facilitate relative location of the wafer and the first and second laser beams.

Advantageously, the apparatus further comprises switching means for switching control pulses between the first laser and the second laser.

Conveniently, the switching means is arranged to switch output control pulses between the first laser and second laser on receipt of a trigger pulse in a train of control pulses received by the switching means.

The invention will now be described, by way of example, with reference to the accompanying drawings in which:

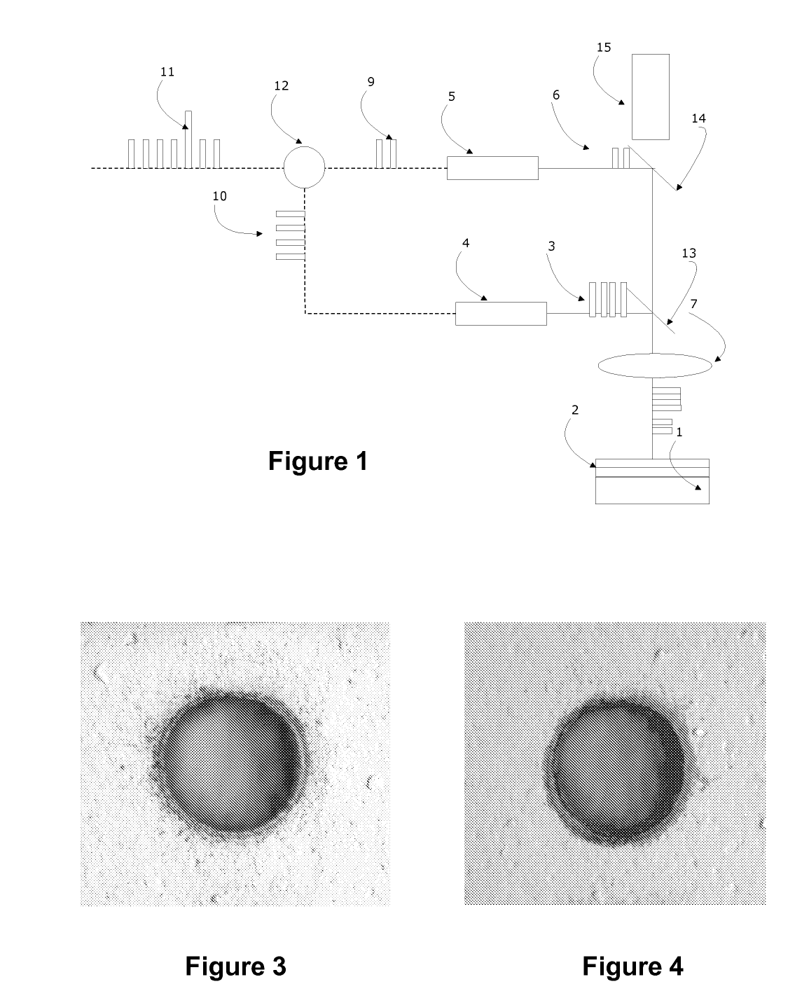

FIG. 1 is a schematic diagram of an apparatus according to the invention;

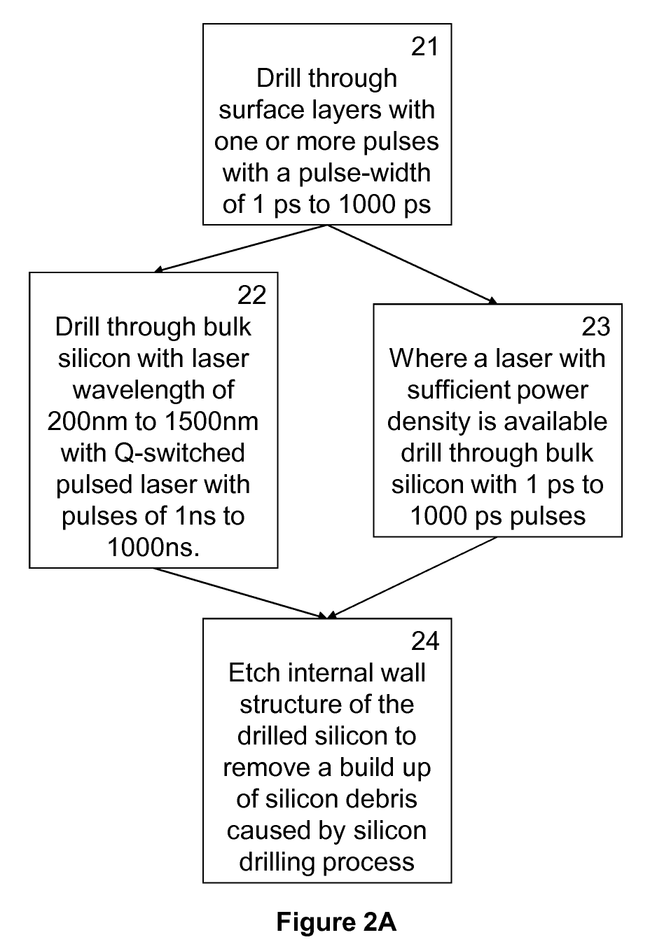

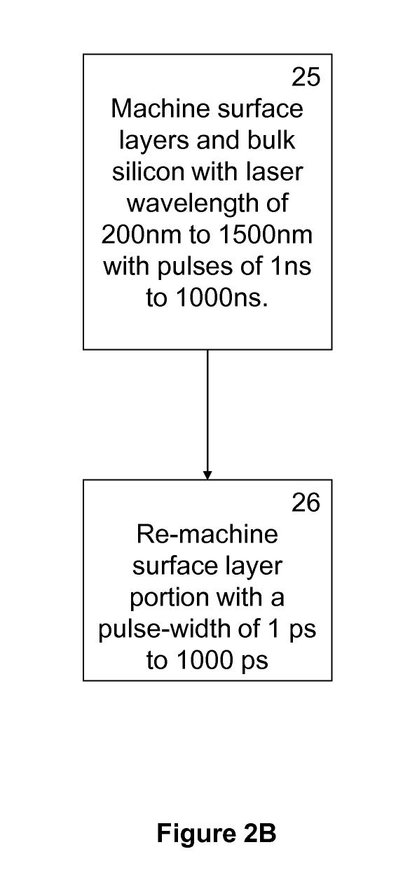

FIGS. 2A and 2B are flowcharts of methods according to embodiments of the invention;

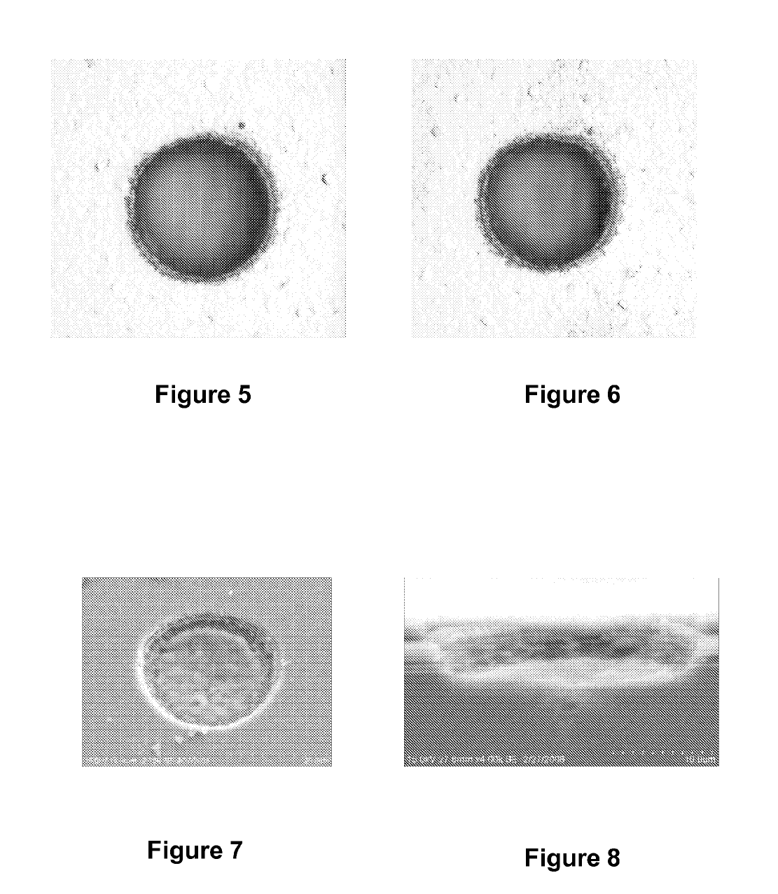

FIGS. 3 to 6 are optical micrographs of a plan view of surface layers drilled for a via with a picosecond pulse laser;

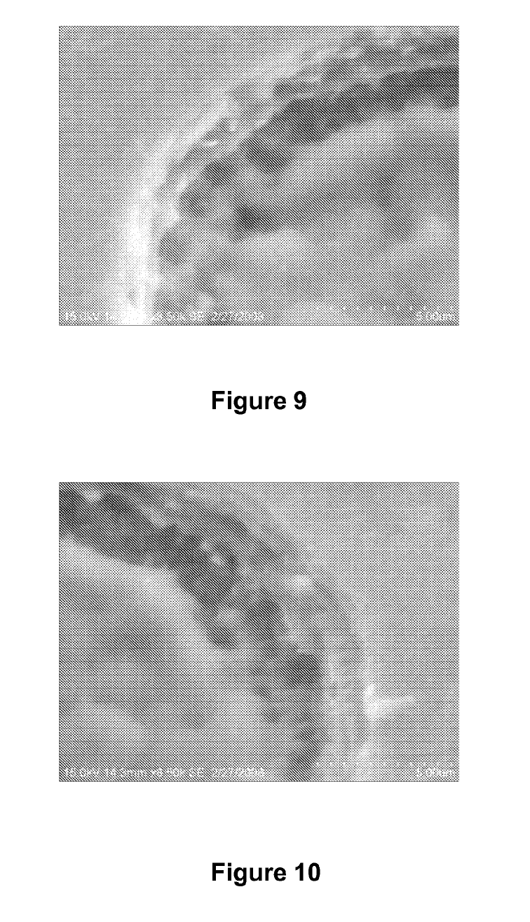

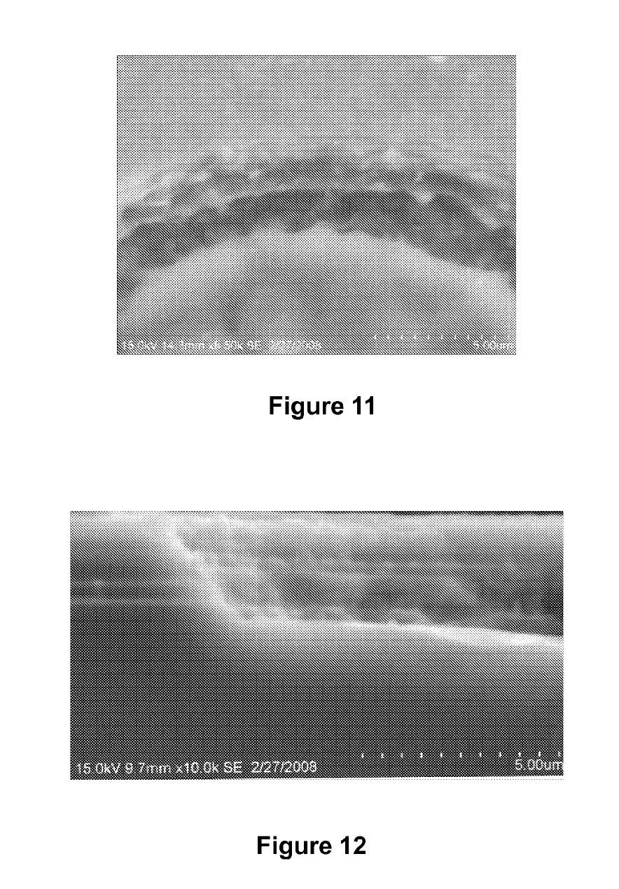

FIGS. 7 to 12 are scanning electron micrographs of plan, side and tilted views of surface layers drilled with a picosecond pulse laser for a via;

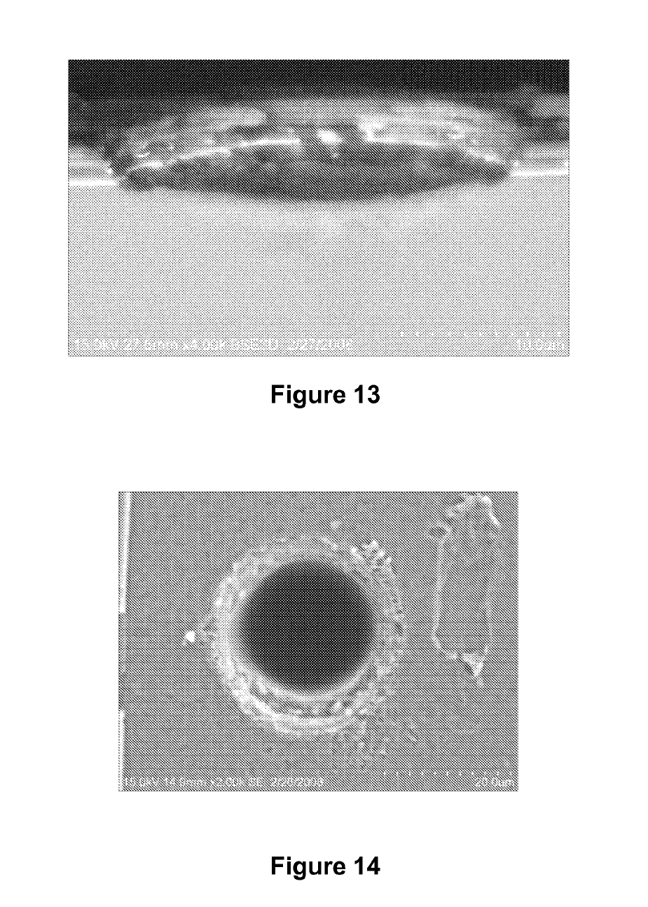

FIG. 13 is a scanning electron micrograph in backscattering mode of surface layers drilled with a picosecond pulse laser for a via;

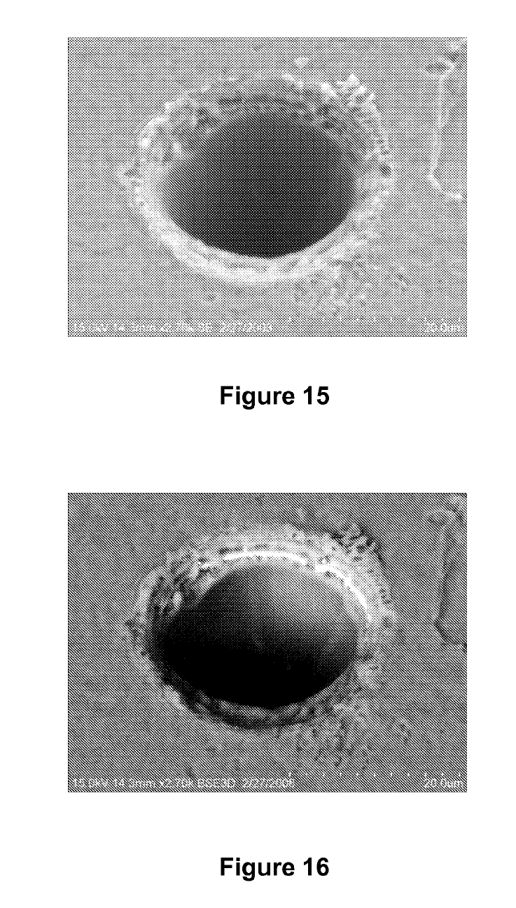

FIGS. 14 and 15 are scanning electron micrographs of plan and tilted views respectively of a via after a second step of the method of the invention of laser drilling a substrate of the wafer;

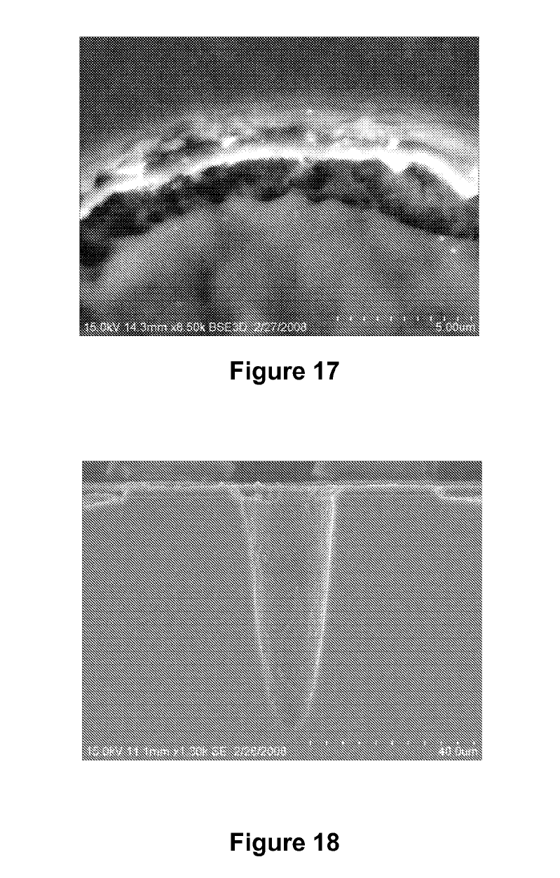

FIGS. 16 and 17 are scanning electron micrographs in backscatter mode of a via after the second step of the method of the invention;

FIG. 18 is an electron scanning micrograph of a via profile after the second step of the method of the invention;

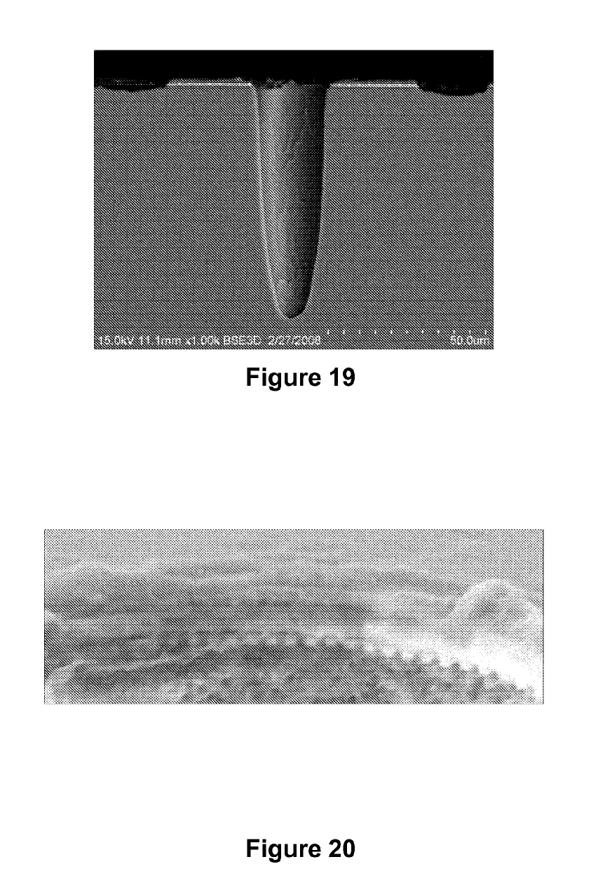

FIG. 19 is an electron scanning micrograph in backscatter mode of the via profile after a second step of the method of the invention;

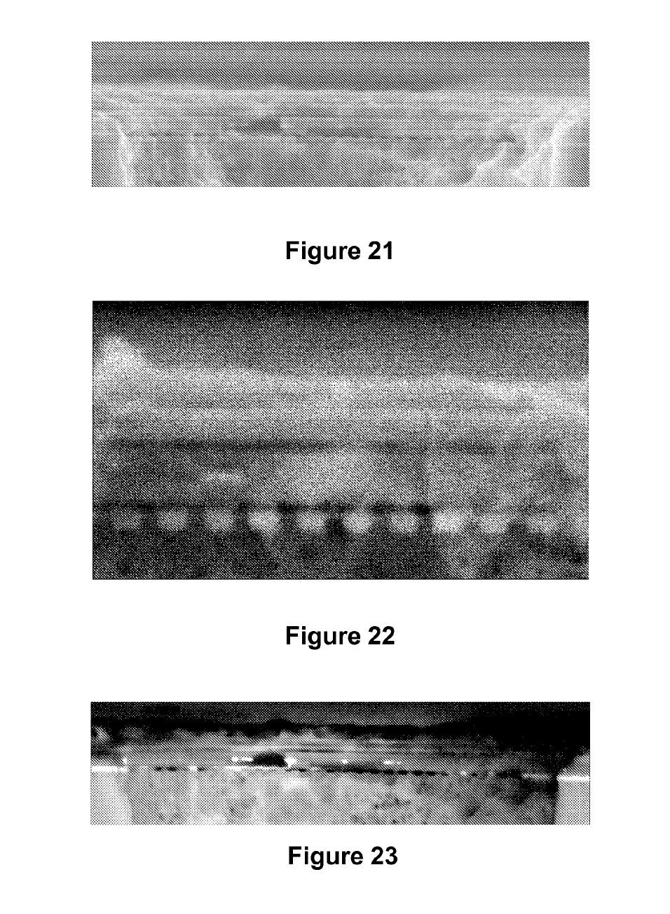

FIGS. 20 and 21 are scanning electron micrographs of an etching process of the invention, showing a side wall;

FIG. 22 is a scanning electron micrograph of the etching process of the invention, in scattered light showing a side wall; and

FIG. 23 is a scanning electron micrograph showing silicon droplets partially removed and clean metal layers.

In the Figures, like reference numerals denote like parts.

Referring to FIG. 1, in an apparatus according to the invention, first and second lasers 4, 5 provide parallel laser beams. A laser beam from the first laser 5 is incident on a folding mirror 14 to deflect the laser beam through 90 deg. in a direction towards the laser beam from the first laser. Both laser beams are thereby incident mutually orthogonally on a beam splitter 13 which deflects the laser beam from the second laser 4 through 90 deg. in a direction away from the laser beam from the first laser 5 so that the two beam paths are alternately coaxially incident on a collimating lens 7 which focuses the laser beams onto a wafer having a substrate 1 and surface layers 2.

The first and second lasers are controlled by respective signal pulses 9, 10. A switch 12 is provided to switch a train of signal pulses from a source, not shown, between the first and second lasers. The switch 12 is controlled by a trigger pulse 11 in the train of pulses switched by the switch 12 to the first laser 5 or the second laser 4.

Thus the apparatus is used to perform a process on a semiconductor wafer by delivering respective laser beams to a same location on the wafer 1, 2. It will be understood that there are a number of approaches that may be used to achieve this. In the approach illustrated in FIG. 1, both lasers beams are propagated collinearly as illustrated following beam path combination in the beam splitter 13. Where the laser beams have different wavelengths the beam splitter may be transparent to a first laser beam from laser 5 and reflective to a second laser beam from laser 4. Alternatively, one skilled in the art will recognise that polarisation or other means of beam combination may be used. This requires careful design of optical parameters in each beam path. The beams may be delivered though a standard lens 7 which may be a compound lens designed to provide a required beam diameter at a focus of each beam. One skilled in the art will realise that wafer positioning may be achieved through use of known and well-established machine vision systems and wafer or beam motion systems so that the laser beams are alternately incident at a required location on the wafer. In the example illustrated in FIG. 1 a machine vision camera 15 is collinear with the beam splitter 13 and a folding mirror 14 to allow imaging of the machining scene and the wafer before, during and after machining.

FIG. 1 shows a typical configuration. Pulse emission from each laser can be synchronised to ensure that transitions from sequential exposure of surface layers to subsequent bulk silicon are instantaneous and in a correct sequence. One such embodiment utilises an electrical circuit as shown in FIG. 1 by which the train of signal pulses 9 is provided to the first laser 5 in order to provide laser beam pulses 6 for drilling the layered structure 2. Once a sufficient number of pulses have been delivered the circuit switches to deliver a train of signal pulses 10 to the second laser 4 using a larger switching or other trigger signal pulse 11 to switch a suitable electrical switch 12. This second laser 4 then emits laser beam pulses 3 for drilling the bulk silicon 1. One skilled in the art will recognise that there are many mechanism to control pulse emissions from the lasers and this invention is not limited to the one described.

Alternatively the laser beams may be displaced with respect to each other. One skilled in the art will recognise that in effect this process requires a known laser placement process applied to each laser using known methods of machine vision and wafer placement mentioned previously.

In a method according to the invention, problems which are associated with known etch processes are overcome by using a series of laser drilling or machining steps to perform the required operations. The process steps may be applied for drilling via interconnects and/or for scribing and dicing silicon wafers.

To understand the processes it is necessary to consider the lasers which are used. Known nanosecond lasers such as ultraviolet Q-switched lasers as described in EP 1201108, EP 1328372, EP 1404481, EP 1825507 and WO 2007/088058 can be used in via formation, scribing or dicing. However, in some cases layers of metals and insulators on the wafer surface are damaged excessively using these nanosecond pulse lasers alone.

Accordingly a laser with a pulse width between 1 picosecond (ps) and 1000 ps is used to remove or drill through metals and insulators on a surface of a wafer without inducing collateral damage. A layer stack is removed or drilled according to the invention using a short pulse laser.

Referring to FIGS. 1 and 2A, the full laser process therefore involves the following:

Step 1: Drilling 21 through a layered medium 2 comprising one or more layers on a surface of a wafer using a first laser 5 with one or more laser pulses 6 with a pulse-width between 1 ps and 1000 ps.

Step 2: Drilling 22 through the bulk silicon wafer 2 using a Q-switched pulsed laser 4 with a wavelength between 200 nm and 1500 nm and pulses 3 which are between 1 ns and 1000 ns. Alternatively, where a laser with sufficient power density is available to achieve a desired throughput, drilling 23 may be performed with a short pulse laser similar to the picosecond pulse laser used in surface layer removal or drilling.

Step 3: Etching 24 the wall structure of the drilled or machined silicon to remove a build up of silicon debris caused by the silicon drilling process.

### EXAMPLE

### Result of the First Step of the Process

### Cutting Through Active Layers by Picosecond Pulse Laser Beam

Optical microscope images of surface layers drilled for vias with the ps laser alone are shown in FIGS. 3 to 6. Active layers that have been exposed are sharp and layers are well-distinguished as observed on SEM-images shown in FIGS. 7 to 13. In addition, particles and debris on the surface are minimal.

Result of the second step of the process: intra volume Si laser drilling

60-70 μm deep vias of ˜24 μm diameter are drilled intra volume after manual alignment with vias of ˜28 μm diameter machined earlier by picosecond pulse laser in the active layers. FIGS. 14 to 19 show SEM images of the resulting vias.

From the cross-sectional and the angled views obtained from the SEM it is evident the picosecond laser alone drills cleanly through the structured layers, leaving each intact and well defined. When a nanosecond pulse laser is subsequently used to drill the silicon substrate the active layers become coated with recast silicon.

Without using the picosecond laser pulses, typically the inside of the via includes metal particles. Using the picosecond pulse laser to drill the active layers, no metal is present in the vias. Using an etchant which reacts with silicon but not metal, re-deposited silicon may be etched without masking since the majority of the wafer's surface is metal and polyimide forming a self-aligned mask for etching inner walls of the vias.

### Result of a Third Step of the Process: Etching.

Referring to FIGS. 20 to 23, to remove adhered silicon debris around the multilayer stack, the samples are subjected to a short XeF₂ etch cycle, successful results of which can be seen in the Figures.

The invention is not limited to the use of XeF₂ as the etchant. Other etchants such as “noble halogens” or “inter-halides” in either liquid or gas form may alternatively be used. Wet chemical etch using KOH, tetramethylammonium hydroxide (TmaH) or other chemicals known to one skilled in the art may alternatively be used selectively to remove silicon. Finally, plasma etching and reactive ion etching may alternatively be used to perform the final step.

Referring to FIG. 2B, in another embodiment of the invention, a similar result may be achieved by reversing the order of picosecond pulse laser and bulk silicon nanosecond pulse laser. To achieve the same effect in this instance, layers on the surface are machined 25 coarsely by the bulk silicon laser as part of the bulk silicon machining process. Following this process the metal and insulator layers are exposed to the picosecond laser with a beam profile such that machining 26 of the metal layers is performed to widen the via aperture at the metal and insulator layers and to provide a similar clean cut and finish as in the case where the metal insulator layers are machined first.

1. A method of machining, or forming a feature in, a patterned silicon wafer comprising:
a. removing portions of surface layers on the wafer using a first pulsed laser beam with a first wavelength and with a pulse width between 1 ps and 1000 ps; and
b. removing portions of bulk silicon underlying the surface layers from the wafer using a second pulsed laser beam with a second wavelength of between 200 nm and 1100 nm, shorter than the first wavelength.

2. A method as claimed in claim 1 comprising removing re-deposited silicon from the wafer by etching.

3. A method as claimed in claim 1, wherein the first pulsed laser beam has wavelength between 1000 nm and 1100 nm.

4. A method as claimed in claim 1, wherein the second pulsed laser beam is produced by a Q-switched laser with a pulse width in the range 1 ns to 500 ns

5. A method as claimed in claim 1, wherein the second pulsed laser beam has a pulse width between 1 ps and 1000 ps.

6. A method as claimed in claim 2, comprising etching with xenon difluoride.

7. A method as claimed in claim 2, comprising a wet chemical etch.

8. A method as claimed in claim 2, comprising a dry chemical etch.

9. A method as claimed in claim 2 where the etch process is used to clear at least one of the surface of the wafer and the machined walls of the wafer of debris.

10. A method as claimed in claim 1, comprising forming an interconnecting through via or blind via in the wafer.

11. A method as claimed in claim 1, comprising dicing or singulating a wafer.

12. An apparatus arranged to machine, or form a feature in, a patterned silicon wafer comprising:
a. a first laser arranged to provide a first pulsed laser beam with a first wavelength and a pulse width between 1 ps and 1000 ps arranged to remove portions of surface layers on the wafer;
b. a second laser arranged to provide a second pulsed laser beam with a wavelength of between 200 nm and 1100 nm, shorter than the first wavelength and arranged to remove portions of bulk silicon underlying the surface layers from the wafer; and
c. a beam positioning system for targeting the first and second laser beams at a same location on the wafer.

13. An apparatus as claimed in claim 12 comprising an etchant exposure system arranged to remove re-deposited silicon from the wafer by etching.

14. An apparatus as claimed in claim 12, wherein the first pulsed laser beam has a wavelength between 1000 nm and 1100 nm.

15. An apparatus as claimed in claim 12, wherein the second laser is a Q-switched laser with a pulse width in the range 1 ns to 500 ns.

16. An apparatus as claimed in claim 12, wherein the second pulsed laser beam has a pulse width between 1 ps and 1000 ps.

17. An apparatus as claimed in claim 12 comprising beam directing optics for aligning paths of the first and second laser beams coaxially for targeting at a same location on the wafer.

18. An apparatus as claimed claim 13, wherein etchant exposure system is arranged to etch with xenon difluoride.

19. An apparatus as claimed in claim 13, wherein the etchant exposure system is arranged to provide a wet chemical etch.

20. An apparatus as claimed in claim 13, wherein the etchant exposure system is arranged to provide a dry chemical etch.

21. An apparatus as claimed in claim 13, wherein the etchant exposure system is arranged to provide a wet chemical etch to clear the surface of the wafer and machined walls of the wafer of debris.

22. An apparatus as claimed in claim 12, arranged to form an interconnecting through via or blind via in the wafer.

23. An apparatus as claimed in claim 12, arranged to dice or singulate a wafer.

24. An apparatus as claimed in claim 12, comprising a synchronising laser control source arranged to sequence pulse emissions from the first and second lasers to deliver pulses of each laser in a predetermined sequence to the wafer.

25. An apparatus as claimed in claim 12 comprising a machine vision system arranged to image through the laser beam path to facilitate relative location of the wafer and the first and second laser beams.

26. An apparatus as claimed in claim 12 comprising an electrical switch for switching control pulses between the first laser and the second laser.

27. An apparatus as claimed in claim 26 wherein the electrical switch is arranged to switch output control pulses between the first laser and second laser on receipt of a trigger pulse in a train of control pulses received by the electrical switch.
